(19) United States
(12) Patent Application Publication
(10) Pub. No.: US 2013/0334597 A1
(43) Pub. Date: Dec. 19, 2013

(54) POWER SEMICONDUCTOR DEVICE

(71) Applicants: Hiroaki Yamashita, Hyogo (JP); Masaru Izumisawa, Hyogo (JP); Syotaro Ono, Hyogo (JP); Hiroshi Ohta, Hyogo (JP)

(72) Inventors: Hiroaki Yamashita, Hyogo (JP); Masaru Izumisawa, Hyogo (JP); Syotaro Ono, Hyogo (JP); Hiroshi Ohta, Hyogo (JP)

(21) Appl. No.: 13/720,344

(22) Filed: Dec. 19, 2012

(30) Foreign Application Priority Data
Jun. 13, 2012 (JP) 2012-134217

(51) Int. Cl. H01L 29/78; H01L 29/66

(52) U.S. Cl. CPC H01L 29/7813; H01L 29/66734
USPC 257/334; 438/270

(57) ABSTRACT

A power semiconductor device includes a first semiconductor layer of a first conductivity type, a second semiconductor layer of the first conductivity type having an effective impurity concentration that is less than an effective impurity concentration of the first semiconductor layer arranged on the first semiconductor layer, a third semiconductor layer of a second conductivity type arranged on the second semiconductor layer, and a gate electrode formed in the first second semiconductor layer and the third semiconductor layer, wherein at least two regions are formed in the power semiconductor device, and a threshold voltage of the first region is different from a threshold voltage of the second region.

### CROSS-REFERENCE TO RELATED APPLICATION

This application is based upon and claims the benefit of priority from Japanese Patent Application No. 2012-134217, filed Jun. 13, 2012; the entire contents of which are incorporated herein by reference.

### FIELD

Embodiments described herein relate to a power semiconductor device.

### BACKGROUND

In power electronic circuits, power semiconductor devices, such as the MOSFET (metal-oxide-semiconductor field effect transistor) and IGBT (insulated gate bipolar transistor), are commonly used. In these devices, if the pitch of the unit cells is decreased, the channel density can be increased. This can improve the trade-off relationship between a high voltage rating and a low ON resistance. As a result, the chip size can be reduced, the cost for each chip can be reduced, and, at the same time, the capacitance is decreased, which improves switching characteristics.

However, when power semiconductor devices have switching speed increased in this manner, the devices encounter operational problems. For example, when power semiconductor devices are used in some applications that do not require high-speed operation, the variation of the current over time (hereinafter to be referred to as di/dt) may become excessively large. This is applied to a parasitic inductance associated with an external load, (e.g., the effective or combined load of the intended connection and/or an external circuit, or the like) which generates a surge voltage. Further, the EMI (electromagnetic interference) characteristics of the power semiconductor device may be degraded.

### DESCRIPTION OF THE DRAWINGS

FIG. 1A is a partial plan view of an example of a semiconductor portion of the power semiconductor device according to a first embodiment. FIG. 1B is a partial cross-sectional view taken across line A-A′ in FIG. 1A. FIG. 1C is a partial cross-sectional view taken across line B-B′ in FIG. 1A.

FIG. 2 is a graph illustrating the I-V characteristics of a power semiconductor device. Here, the abscissa represents the gate-source voltage and the ordinate represents the source-drain current.

FIG. 3A and FIG. 3B are graphs illustrating the operation of a power semiconductor device. Here, the abscissa represents time and the ordinate represents the gate-source voltage and the source-drain current, respectively. FIG. 3A illustrates the operation of the first embodiment and FIG. 3B illustrates the operation of a comparative example.

FIGS. 4A to 4C are partial plan views of an example of a semiconductor portion of the power semiconductor device according to a second embodiment. FIG. 4B is a partial cross-sectional view taken across line C-C′ in FIG. 4A and FIG. 4C is a partial cross-sectional view taken across line D-D′ in FIG. 4A.

FIG. 5A is a partial plan view of an example of a semiconductor portion of the power semiconductor device according to a third embodiment. FIG. 5B is a partial cross-sectional view taken across line E-E′ in FIG. 5A and FIG. 5C is a partial cross-sectional view taken across line F-F′ in FIG. 5A.

FIG. 6 is a partial plan view of an example of a semiconductor portion of the power semiconductor device according to a modified example of the third embodiment.

### DETAILED DESCRIPTION

In general, according to one embodiment, the invention will be explained with reference to figures.

The purpose of the present disclosure is to provide a power semiconductor device with reduced variation of current over time during the switching operation.

### First Embodiment

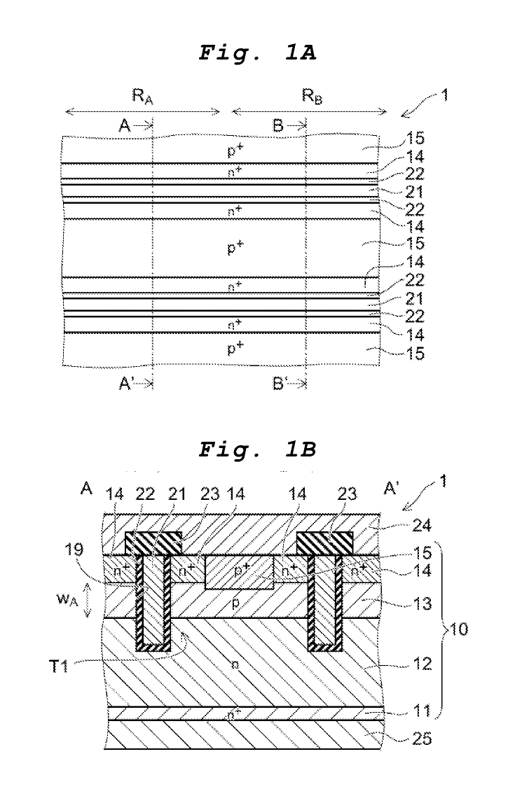

FIG. 1A to FIG. 1C are schematic views illustrating a portion of the power semiconductor device according to this embodiment. FIG. 1A is a plan view of a surface of a semiconductor portion of the power semiconductor device of FIGS. 1B and 1C. FIG. 1B is a partial cross-sectional view taken across line A-A′ in FIG. 1A. FIG. 1C is a partial cross-sectional view taken across line B-B′ in FIG. 1A.

The power semiconductor device according to this embodiment has a first semiconductor layer of a first conductivity type, a second semiconductor layer of a second conductivity type arranged on the first semiconductor layer, a third semiconductor layer of the first conductivity type arranged on the second semiconductor layer, a gate electrode, and a gate insulating film arranged between the gate electrode and the first, second, and third semiconductor layers. With the first semiconductor layer, the second semiconductor layer, the third semiconductor layer, the gate electrode, and the gate insulating film, a field effect transistor is formed, and the threshold voltage of the transistor in a first region is higher than the threshold voltage of the transistor in a second region.

As shown in FIG. 1A to FIG. 1C, with primary reference to FIGS. 1B and 1C, in the power semiconductor device 1 of this embodiment, an n+ type drain layer 11 is arranged. On the drain layer 11, an n type drift layer 12 is arranged. On the drift layer 12, a p type base layer 13 is arranged. On the base layer 13, plural strip-shaped n+ type source layers 14 and plural p+ type contact layers 15 extending unidirectionally thereon, are arranged alternately to form an array, as shown in FIG. 1A. The drain layer 11, drift layer 12, base layer 13, source layers 14 and contact layers 15 form a semiconductor portion 10. In one example, the semiconductor portion 10 may be made of monocrystalline silicon, and each layer has a certain quantity of impurity implanted therein to provide an n type or p type conductivity. On the upper surface of the semiconductor portion 10, the source layers 14 and contact layers 15 are exposed as shown in FIG. 1A. On the other side of the semiconductor portion 10, a drain electrode 25 made of, for example, a metal, is arranged beneath the semiconductor portion 10, and it is electrically connected with the drain layer 11 as shown in FIGS. 1B and 1C.

On the semiconductor portion 10, plural trenches 19 are formed from the upper surface side. Here, the trenches 19 are arranged in the central portion of the semiconductor portion 10 and in between the source layers 14. The trenches 19 also extend in the same plane direction as the source layers 14. In each of the trenches 19, a trench gate electrode 21 made of an electroconductive material, for example, polysilicon having an implanted impurity, is embedded. The trench gate electrode 21 extends through the source layer 14 and base layer 13 to reach the interior of the drift layer 12. That is, in the vertical direction shown in FIGS. 1B and 1C, the upper end of the trench gate electrode 21 is provided at about the same height as the upper surface of the source layer 14 (i.e., substantially coplanar), and the lower end of the trench gate electrode 21 is located between the upper surface of the drift layer 12 and the lower surface thereof. A gate insulating film 22 made of, for example, silicon oxide, is arranged between the trench gate electrode 21 and the semiconductor portion 10.

An insulating film 23 made of, for example, silicon oxide, is arranged in the region just above the trench gate electrode 21. A source electrode 24 made of, for example, a metal, is arranged above the semiconductor portion 10 and the insulating film 23, and it is connected with the source layer 14 and contact layer 15. The source electrode 24 is insulated from the trench gate electrode 21 by the insulating film 23. In FIG. 1A, the insulating film 23 and source electrode 24 are not shown to illustrate the upper surfaces of the source layers 14, the contact layers 15, the trench gate electrodes 21 and the gate insulating film 22.

In the power semiconductor device 1, region R_{A} and region R_{B} are set. Here, a thickness w_{A} of the portion of the base layer 13 arranged in region R_{B} is greater than a thickness w_{A} of the portion of the base layer 13 arranged in region R_{A}. The structure of the semiconductor portion 10 can be formed by having different depths for the source layers 14. That is, after formation of the base layer 13 having a variable thickness, as the source layer 14 is formed on the upper layer portion of the base layer 13, if the source layer 14 is shallower, and the base layer 13 correspondingly becomes thicker. In order to have different depths for the source layer 14 in region R_{A} and region R_{B}, for example, when ion implanting is carried out to form source layer 14, the film thickness of the silicon oxide film (not shown in the figure) formed on the semiconductor portion 10 is varied, so that the depths that can be reached by the dopant ions also vary. As another example that may be used, the source layers 14 may be formed to be separated from each other.

In the following, the operation of the power semiconductor device according to the present embodiment will be explained.

As shown in FIG. 1A to FIG. 1C, in the power semiconductor device 1 of the present embodiment, the drain layer 11, drift layer 12, base layer 13, source layers 14, contact layers 15, trench gate electrode 21 and gate insulating film 22 form a vertical n channel type field-effect transistor T1. In this transistor T1, the region containing base layer 13 connected with the gate insulating film 22 is taken as the channel region, and an electron current flows from the source layers 14 towards the drift layer 12.

Because thickness w_{B} of the base layer 13 in region R_{B} is thicker than the thickness w_{A} of the base layer 13 in region R_{A}, the channel length of the transistor T1 in region R_{B} is longer than the channel length of the transistor T1 in region R_{A}. Consequently, the threshold voltage of the transistor T1 in region R_{B} is also higher than the threshold voltage of the transistor T1 in region R_{A}. In addition, even if the peak concentrations of the impurity in the base layer 13 between the region R_{A} and the region R_{B} are different due to the difference in the ion implanting conditions for forming the source layers 14, the threshold voltages of the transistors T1 are different. That is, the higher the effective impurity concentration in the base layer 13, the higher the threshold voltage of the transistor T1.

In the example shown in FIG. 1A to FIG. 1C, two regions, that is, region R_{A} and region R_{B}, are provided in the power semiconductor device 1. However, region R_{A} and region R_{B} may each be arranged at plural sites. Additionally, in the power semiconductor device 1, three or more types of regions may be provided. In this case, different types of regions may have different threshold voltages of the transistor T1. As a result, the transistors T1 have three or more threshold voltages. In addition, the ratio of the size of different regions may be selected appropriately.

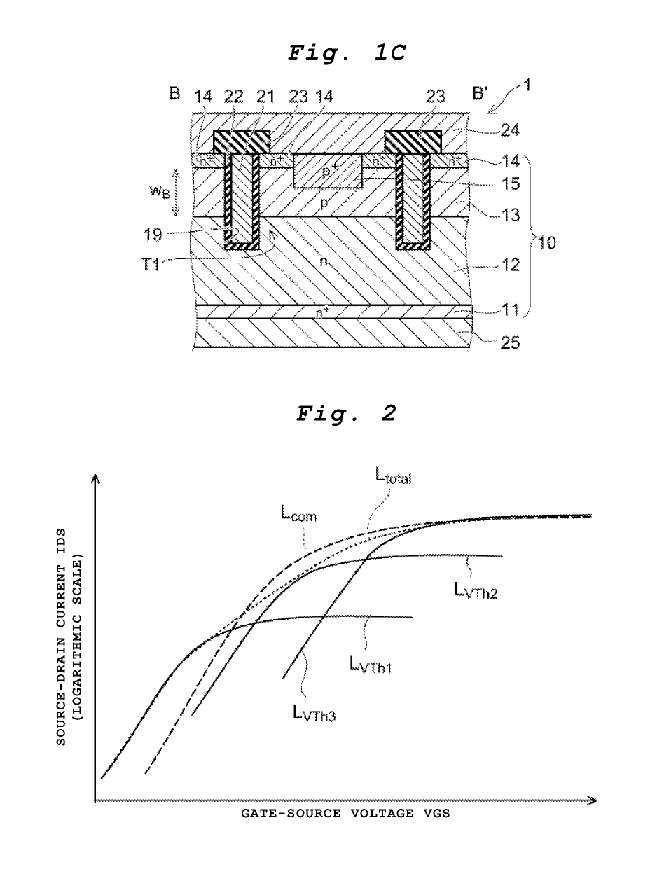

FIG. 2 is a graph illustrating the I-V characteristics of a power semiconductor device. Here, the abscissa represents the gate-source voltage and the ordinate represents the source-drain current.

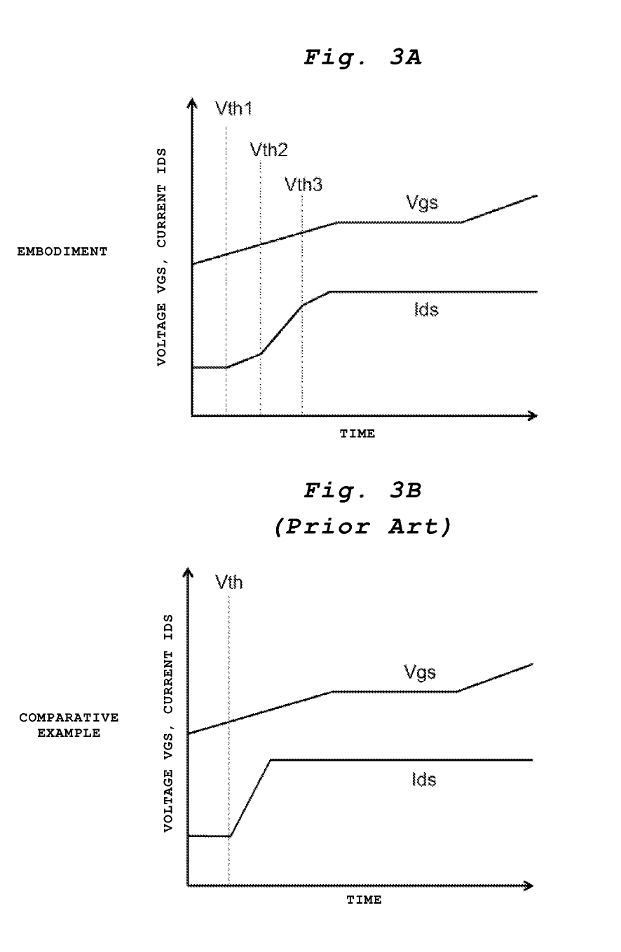

FIG. 3A and FIG. 3B are graphs illustrating the operation of a power semiconductor device. Here, the abscissa represents time and the ordinate represents the gate-source voltage and source-drain current, respectively. FIG. 3A shows the present embodiment and FIG. 3B shows a comparative example.

FIG. 2 and FIG. 3A illustrate an example in which three different types of regions are set in the power semiconductor device 1 according to the present embodiment, and they have different thresholds. The ratio of the size of these regions is set at about 1:10:100. That is, the size of the region having the lowest threshold Vth1 is taken as 1, the size of the region having the second lowest threshold Vth2 is 10, and the size of the region having the highest threshold Vth3 is 100. As a result, the ratio of the ON currents of the various regions becomes nearly 1:10:100.

On the other hand, FIG. 3B illustrates a power semiconductor device in a comparative example. In a conventional power semiconductor device, the base layer has a uniform thickness, so that the channel length of the transistor is also uniform, and the threshold is one level.

As shown in FIG. 2, for the power semiconductor device of the present embodiment, when the gate-source voltage Vgs is increased continuously from that in the state in which the entirety of the transistor T1 is off, as indicated by the solid line Lvth1, the transistor T1 is turned on in the region where the threshold is Vth1, and the source-drain current Ids starts flowing. As voltage Vgs is further increased, as indicated by the solid line Lvth2, the transistor T1 is also turned on in the region where the threshold is Vth2, and the current Ids is increased. As the voltage Vgs is further increased, as indicated by the solid line Lvth3, the transistor T1 is also turned on in the region where the threshold is Vth3, and the current Ids is further increased. In this way, as indicated by broken line Ltotal, for the entirety of the power semiconductor device 1, the current Ids may be continuously increased.

Consequently, as shown in FIG. 3A, even when the switching speed of the power semiconductor device 1 is increased, as the transistor T1 is sequentially turned on for the regions one by one, the variation over time of the current Ids (di/dt) is smaller as compared to the current Ids of FIG. 3B. As a result, the surge voltage that is caused by parasitic inductance of an external load of the intended connection and/or an external circuit connected with the power semiconductor device 1 is decreased, and the switching noise can thus be suppressed.

On the other hand, for the power semiconductor device according to the comparative example (i.e., a conventional power semiconductor device), as the voltage Vgs surpasses the threshold Vth, current Ids rises drastically, as indicated by the broken line L_{com} shown in FIG. 2.

Consequently, as shown in FIG. 3B, for the power semiconductor device, as the switching speed is increased, the variation over time of the current Ids (di/dt) becomes larger, and the switching noise caused by the parasitic inductance of the external load is greater.

As explained above, for the power semiconductor device 1 of the present embodiment, plural regions are provided and the thicknesses of the base layer 13 are different for the different regions. Consequently, the channel lengths of the transistor T1 become different, and the threshold voltages of the transistor T1 are different. As a result, when the gate voltage Vgs is continuously increased, the various regions are sequentially turned on from the off state, so that variation over time of the source-drain current Ids (di/dt) can be suppressed. As a result, for the power semiconductor device 1, even when it is connected with an external load, an external circuit, or other load connection that does not perform a high-speed operation, it is still possible to suppress the switching noise.

### Second Embodiment

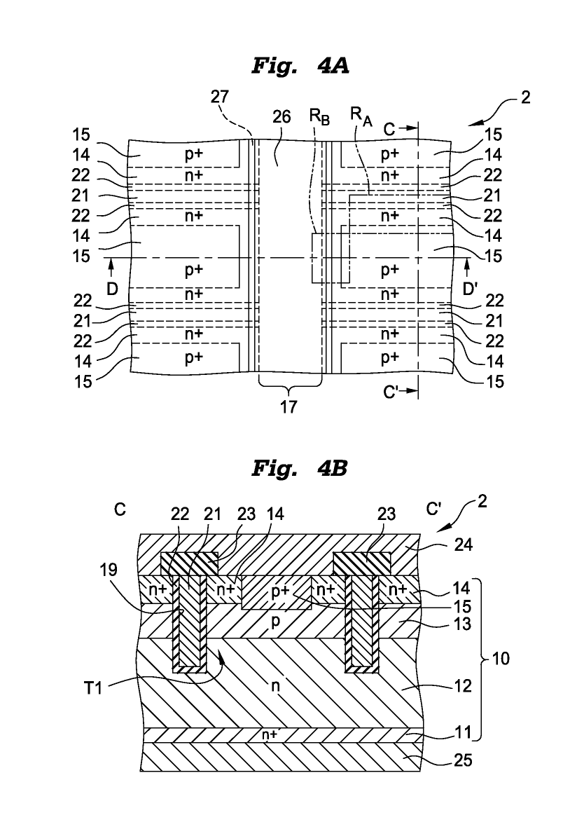

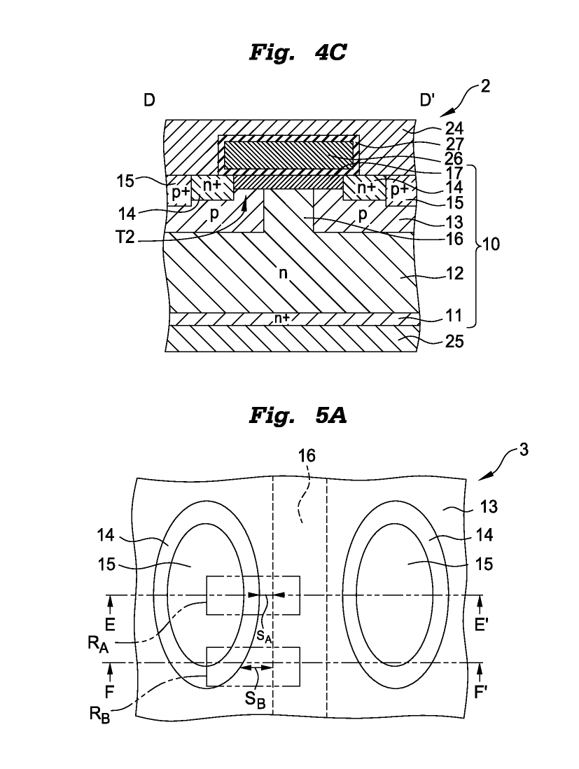

FIG. 4A to FIG. 4C are schematic views illustrating a portion of the power semiconductor device according to the second embodiment. FIG. 4A is a plan view of a surface of a semiconductor portion of the power semiconductor device of FIGS. 4B and 4C. FIG. 4B is a partial cross-sectional view taken across line C-C′ in FIG. 4A. FIG. 4C is a partial cross-sectional view taken across line D-D′ in FIG. 4A.

As shown in FIG. 4A to FIG. 4C, for the power semiconductor device 2 according to the present embodiment, for example, an n+ type drain layer 11, an n type drift layer 12 and a p type base layer 13 are arranged sequentially from the lower side of a semiconductor portion 10. On the base layer 13, n+ type source layers 14 and p+ type contact layers 15 are arranged. As shown in the plan view, the contact layers 15 are arranged in a matrix configuration in plural rectangular regions, and the source layers 14 are arranged around the contact layers 15, respectively. In the source layers 14, there are portions extending in two directions orthogonal to each other along the edges of the rectangular contact layers 15.

Also, as shown in FIG. 4C, on the drift layer 12, an n type junction layer 16 is arranged. The junction layer 16 extends unidirectionally along the edges of the contact layers 15, and it is in contact with the drift layer 12 and protrudes up from the drift layer 12 to enter the base layer 13. The junction layer 16 is separated from the source layers 14 and contact layers 15 by the base layer 13.

In addition, a variable conductivity layer 17 is provided in the region just above the junction layer 16 and its periphery. The variable conductivity layer 17 comprises a layer where the effective impurity concentration of the semiconductor material is adjusted. The lower surface of the variable conductivity layer 17 is in contact with the upper surface of the junction layer 16, and its side surface is in contact with the source layers 14. In one aspect, the variable conductivity layer 17 may have a conductivity type of, for example, the p type. The effective impurity concentration of the variable conductivity layer 17 is different from the effective impurity concentration of the base layer 13. In another aspect, the conductivity type of the variable conductivity layer 17 may be, for example, the n type. In the present specification, “effective impurity concentration” refers to the concentration of the impurity (e.g., dopants) that provides the desired electroconductivity of the respective semiconductor material. For example, when the semiconductor material contains both the impurity as a donor and the impurity as an acceptor, the concentration refers to the concentration of donor and acceptor obtained, and excludes a concentration where the donor and the acceptor cancel each other.

The drain layer 11, drift layer 12, base layer 13, source layers 14, contact layers 15, junction layer 16 and variable conductivity layer 17 form the semiconductor portion 10. On the upper surface of the semiconductor portion 10, the source layers 14, contact layers 15 and variable conductivity layer 17 are exposed as shown in FIG. 4A. On the other side of the semiconductor portion 10, a drain electrode 25 is arranged on the lower portion of the semiconductor portion 10, and it is electrically connected with the drain layer 11 as shown in FIGS. 4B and 4C.

In the semiconductor portion 10, plural trenches 19 are formed from the upper surface side. The trenches 19 extend in a plane direction (e.g., into the paper as shown in FIG. 4B) that is orthogonal to the plane direction of the junction layer 16 (e.g., into the paper as shown in FIG. 4C), and the trenches 19 are arranged laterally in between the source layers 14 which extend in the same plane direction as the source layers 14 (e.g., into the paper as shown in FIG. 4B). In each of the trenches 19, a trench gate electrode 21 is embedded. The trench gate electrode 21 extends through the source layer 14 and base layer 13 to reach the interior of the drift layer 12. A gate insulating film 22 is arranged between the trench gate electrode 21 and the semiconductor portion 10. An insulating film 23 is arranged in the region just above the trench gate electrode 21.

On the semiconductor portion 10, a planar gate electrode 26 made of, for example, polysilicon doped with an impurity, is provided. The planar gate electrode 26 comprises a ribbon or strip shape extending in a plane direction (e.g., into the paper as shown in FIG. 4C) that is orthogonal to the plane direction (e.g., into the paper as shown in FIG. 4B) of the trench gate electrode 21. In other words, the planar gate electrode 26 extends in the same plane direction as the junction layer 16. Here, the planar gate electrode 26 is provided in the region just above the variable conductivity layer 17 as shown in FIG. 4C. The variable conductivity layer 17 is provided laterally among the source layers 14 which are arranged on and in contact with the two sides of the variable conductivity layer 17. The surface of the planar gate electrode 26 is covered with, for example, a gate insulating film 27 made of, for example, silicon oxide. Consequently, a portion of the gate insulating film 27 is provided between the planar gate electrode 26 and the variable conductivity layer 17, as well a portion of the source layers 14.

On the semiconductor portion 10, insulating film 23, planar gate electrode 26, gate insulating film 27, and the source electrode 24 are arranged and are connected with the source layers 14 and contact layers 15. The source electrode 24 is insulated from the trench gate electrode 21 by the insulating film 23 and, at the same time, it is insulated from the planar gate electrode 26 by the gate insulating film 27. In FIG. 4A, the source electrode 24, insulating film 23 and gate insulating film 27 are not shown to illustrate the upper surfaces of the source layers 14, the contact layers 15, the trench gate electrodes 21 and the gate insulating film 22, as well as the upper surface of the variable conductivity layer 17. Additionally, a drain electrode 25 is provided through a drain layer 11 in bottom the semiconductor portion 10.

In the following, the operation of the power semiconductor device according to the present embodiment will be explained.

As shown in FIG. 4A and FIG. 4B, in the power semiconductor device 2 according to the present embodiment, in the region R_{A} where source layers 14 face the trench gate electrode 21, the drain layer 11, drift layer 12, base layer 13, source layers 14, contact layers 15, trench gate electrode 21 and gate insulating film. 22 form a vertical N channel type field effect transistor T1. In this transistor T1, the region of the base layer 13 in contact with the gate insulating film 22 is taken as the channel region, and a current flows from the source layers 14 to the drift layer 12.

On the other hand, as shown in FIG. 4A and FIG. 4C, in the power semiconductor device 2, in the region R_{B} where the source layers 14 are adjacent to the planar gate electrode 26, the drain layer 11, drift layer 12, junction layer 16, variable conductivity layer 17, source layers 14, contact layers 15, planar gate electrode 26 and gate insulating film 27 form a horizontal N channel type field effect transistor T2. In this transistor T2, the region of the variable conductivity layer 17 in contact with the gate insulating film 27 is taken as the channel region, and a current flows from the source layers 14 to the junction layer 16. In FIG. 4A, the region R_{A} and region R_{B} are only partially shown.

The effective impurity concentration of the variable conductivity layer 17 is different from the effective impurity concentration of the base layer 13. That is, the effective impurity concentration of the channel region of the transistor T2 is different from the effective impurity concentration of the channel region of the transistor T1. Consequently, the threshold voltage of the transistor T2 formed in the region R_{B} is different from the threshold voltage of the transistor T1 formed in the region R_{A}. For example, when the effective impurity concentration of the variable conductivity layer 17 is higher than the effective impurity concentration of the base layer 13, the threshold voltage of the transistor T2 is also higher than the threshold voltage of the transistor T1.

As shown in FIGS. 4A and 4C, by making an appropriate selection of the ratio of the length of the end edge (e.g., horizontal edge) of the source layer 14 facing the trench gate electrode 21 to the length of the end edge (e.g., vertical edge) facing the planar gate electrode 26, it is possible to select the ratio of the gate width of the transistor T1 to the gate width of the transistor T2, that is, the ratio of the size of the region R_{A} to the size of the region R_{B}. As a result, it is possible to control the ratio of the ON current of the transistor T1 to the ON current of the transistor T2.

According to the present embodiment, just as in the first embodiment, when the gate voltage is increased, the transistors having thresholds different from each other are sequentially turned on, so that the variation over time of the current (di/dt) can be decreased. As a result, even when a high-speed switching operation is carried out, it is still possible to decrease the noise caused by the parasitic impedance of the external load circuit. Except for the characteristic features described with respect to the second embodiment, the second embodiment has the same constitution, operation and effects as those of the first embodiment.

### Third Embodiment

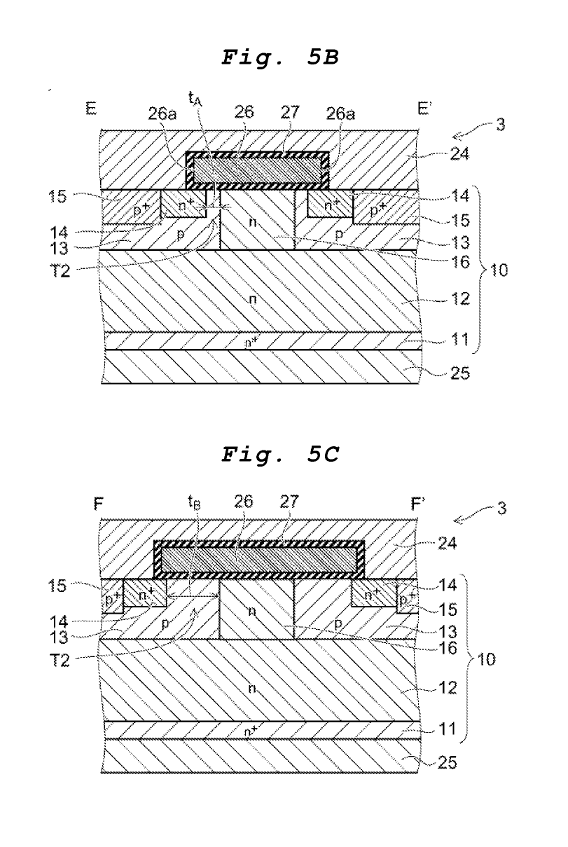

FIG. 5A to FIG. 5C are schematic views illustrating a portion of the power semiconductor device according to the third embodiment. In FIG. 5A, the source electrode 24, the planar gate electrode 26 and gate insulating film 27 are not shown to illustrate the upper surfaces of the base layer 13, the source layers 14, the contact layers 15 and the junction layer 16.

FIG. 5A is a plan view of a surface of a semiconductor portion of the power semiconductor device of FIGS. 5B and 5C. A planar gate electrode 26 is also shown on each side of a junction layer 16, which is shown in phantom in the plan view of FIG. 5A. The planar gate electrode 26 is superimposed on the base layer 13 of the semiconductor portion, which is not shown in FIG. 5A. FIG. 5B is a cross-sectional view taken across line E-E′ in FIG. 5A and FIG. 5C is a cross-sectional view taken across line F-F′ in FIG. 5A.

As shown in FIG. 5A to FIG. 5C, in the power semiconductor device 3 according to this embodiment, for example, an n+ type drain layer 11, an n type drift layer 12 and a p type base layer 13 are arranged sequentially from the lower side. On portions of the base layer 13, the n+ type source layers 14 and p+ type contact layers 15 are set. In the plan view of FIG. 5A, the contact layers 15 are arranged as plural elliptical regions in a matrix configuration, and source layers 14 are arranged as elliptical rings surrounding the contact layers 15, respectively.

Also, on the drift layer 12, an n type junction layer 16 is arranged. As shown in FIG. 5B and FIG. 5C, the junction layer 16 is in contact with the drift layer 12, and it protrudes from the drift layer 12 and extends through the base layer 13. As shown in phantom in FIG. 5A, the junction layer 16 has a ribbon or strip shape that passes through the region between the adjacent source layers 14 and extends unidirectionally thereon. The junction layer 16 is separated from the source layers 14 by the base layer 13, and it is separated from the contact layers 15 by the base layer 13 and the source layers 14.

Here, the drain layer 11, drift layer 12, base layer 13, source layers 14, contact layers 15 and junction layer 16 form the semiconductor portion 10. On the upper surface of the semiconductor portion 10, the base layer 13, source layers 14, contact layers 15 and junction layer 16 are exposed. On the other side of the semiconductor portion 10, the drain electrode 25 is provided, and the lower portion of the semiconductor portion 10 is connected with the drain electrode 25 by the drain layer 11.

On the semiconductor portion 10, a planar gate electrode 26 is provided. In the plan view of FIG. 5A, the planar gate electrode 26 is superimposed on the base layer 13 and has a mesh shape with plural elliptic openings 26a formed in a matrix configuration. The source layers 14 are arranged along the end edges of the openings 26a, respectively. The source layers 14 may be formed in a self-alignment process by ion implanting using the planar gate electrode 26 as a mask. The openings 26a each are located in the region just above the entirety of the contact layer 15 and the inner peripheral portion of the source layer 14. As shown in FIGS. 5B and 5C, the planar gate electrode 26 is provided on portions of the base layer 13 and junction layer 16 on the upper surface of the semiconductor portion 10 and the portions just above the outer peripheral portions of the source layers 14. The outer surface of the planar gate electrode 26 is covered by the gate insulating film 27 made of, for example, silicon oxide. Consequently, a portion of the gate insulating film 27 is arranged between the planar gate electrode 26 and the base layer 13, the junction layer 16 and portions of the source layers 14.

The source electrode 24 is arranged in the upper portion of the semiconductor portion 10, planar gate electrode 26 and gate insulating film 27, and is connected with the source layers 14 and contact layers 15. The source electrode 24 is insulated from the planar gate electrode 26 by the gate insulating film 27. In FIG. 5A, the source electrode 24 and gate insulating film 27 are not shown.

As mentioned previously, in the top view, the openings 26a of the planar gate electrode 26 have an elliptic shape, and the junction layer 16 has a ribbon shape extending in a single direction. Consequently, the distance s between the circumference of the openings 26a and the lateral edge of the junction layer 16 is different. The distance s_{B} from the two ends in the major axial position of the elliptical shape to the junction layer 16 is greater than the distance s_{A} on the extended line of the minor axis of the elliptical shape corresponding to the openings 26a. Because the source layers 14 each are formed along the circumference of the openings 26a, the distance t between the source layers 14 and the junction layer 16 is also different. The distance t_{B} at the two ends in the major axial direction of the elliptical shape is greater than the distance t_{A} on the extended line of the minor axis of the elliptical shape. That is, the distance t_{B} between the source layers 14 and the junction layer 16 in the region R_{B} containing the end in the major axial direction of the elliptic shape corresponding to the openings 26a is greater than the distance t_{A} between the source layers 14 and the junction layer 16 in the region R_{A} containing the minor axis of the elliptic shape. In FIG. 5A, the region R_{A} and region R_{B} are only partially shown.

In the following, the operation of the power semiconductor device according to the present embodiment will be explained.

As shown in FIG. 5A to FIG. 5C, in the power semiconductor device 3 according to the present embodiment, the drain layer 11, drift layer 12, junction layer 16, base layer 13, source layers 14, contact layers 15, planar gate electrode 26 and gate insulating film 27 form a horizontal n channel type field-effect transistor T2. In this transistor T2, the region of the base layer 13 connected with the gate insulating film 27 is taken as the channel region, and a current flows from the source layers 14 to the junction layer 16.

The distances t between the source layers 14 and the junction layer 16 in the various portions of the elliptic shaped source layers 14 are different from each other. For example, as explained above, the distance t_{B} between the source layer 14 and the junction layer 16 in the region R_{B} is longer than the distance t_{A} between the source layer 14 and the junction layer 16 in the region R_{A}. Therefore, the channel length of the transistor T2 in the region R_{B} is longer than the channel length of the transistor T2 in the region R_{A}. Consequently, the threshold voltage of the transistor T2 in the region R_{B} is also higher than the threshold voltage of the transistor T2 in the region R_{A}. However, the distance t does not only assume the values of the two distances t_{A} and t_{B}. Instead, the distance t assumes a distance value that varies continuously according to the circumference of the openings 26a. Consequently, the threshold voltage of the transistor T2 also assumes various values, and the channel length of the transistors is varied. Also, for the shape of the openings 26a, by selecting the eccentricity of the elliptical shape appropriately, it is possible to control the distribution of the ON current with respect to the threshold voltage in the transistor T2.

According to the present embodiment, just as in the first embodiment, when the gate voltage is increased, the transistors with different thresholds are turned on sequentially, so that the variation of the current over time (di/dt) becomes smoother, and it is thus possible to reduce the noise. Also, according to the present embodiment, the channel length of the transistors changes continuously, and the threshold of the transistor T2 varies continuously, so that a smooth variation in the current can be provided efficiently, making it possible to reliably decrease the maximum value of the variation of the current over time (di/dt). As a result, it is possible to reliably decrease the noise. Except for the characteristic features described above, the present embodiment has the same constitution, operation and effects as that of the first embodiment.

In the following, a modified example of the third embodiment will be explained.

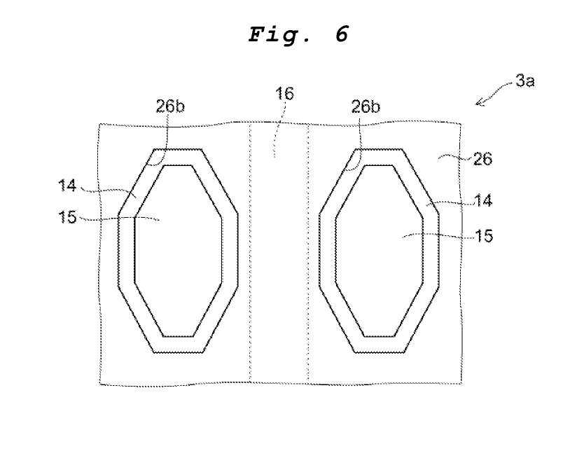

FIG. 6 is a plan view illustrating a power semiconductor device according to this modified example. In FIG. 6, a surface of a semiconductor portion of the power semiconductor device is shown with a planar gate electrode 26 on each side of a junction layer 16. The planar gate electrode 26 is superimposed on the base layer 13 of the semiconductor portion.

As shown in FIG. 6, in the power semiconductor device 3a, in the plan view, the openings 26b of the planar gate electrode 26 are in an octagonal shape. As a result, it is possible to have the channel length of the transistor T2 change continuously similar to the constitution of the power semiconductor device 3 of the third embodiment. Except for the characteristic feature, the present modified example has the same constitution, operation and effects as those of the third embodiment.

The shape of the openings of the planar gate electrode 26 is not limited to the elliptic shape and octagonal shape. As long as the distance between the end edge of the opening and the end edge of the junction layer 16 is constant, other shapes may be used. In addition, the planar gate electrode 26 may not necessarily be provided on the entirety of the region just above the junction layer 16. It is only required that the planar gate electrode be provided in the region just above the portion of the base layer 13, arranged between the source layers 14 and the junction layer 16.

In the embodiments, an explanation has been made on the MOSFET used as the power semiconductor device. However, it is not limited to a certain type of power semiconductor device. It may also be used in IGBT. In the embodiments, the p type and n type may be switched.

According to the embodiments, it is possible to form a power semiconductor device with minor current variation over time in the switching operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power semiconductor device, comprising:
a first semiconductor layer having a first conductivity type;
a second semiconductor layer having the first conductivity type disposed on the first semiconductor layer, the first semiconductor layer having an effective impurity concentration that is greater than an effective impurity concentration of the second semiconductor layer;
a third semiconductor layer having a second conductivity type that is different from the first conductivity type;
a fourth semiconductor layer comprising a plurality of semiconductor layers having the first conductivity type and the second conductivity type; and
a first gate electrode formed between adjacent semiconductor layers of the fourth semiconductor layer, the adjacent layers having the first conductivity type, and the first gate electrode extending to the second semiconductor layer through the third semiconductor layer,
wherein at least two regions are formed in the power semiconductor device, and each of the regions is formed to have a different threshold voltage.

2. The power semiconductor device of claim 1, wherein the at least two regions are formed to have different threshold voltages by varying a thickness of the third semiconductor layer.

3. The power semiconductor device of claim 1, wherein the at least two regions are formed to have different threshold voltages by varying an effective impurity concentration of the third semiconductor layer.

4. The power semiconductor device of claim 1, wherein the first gate electrode and the first, second, third, and fourth semiconductor layers comprise parts of a first transistor.

5. The power semiconductor device of claim 4, further comprising:
a junction layer disposed through the third semiconductor layer to separate portions of the fourth semiconductor layer, the junction layer comprising a protruded portion of the second semiconductor layer.

6. The power semiconductor device of claim 5, wherein a second gate electrode is formed on the junction layer, the second gate electrode comprises a part of a second transistor.

7. The power semiconductor device of claim 6, wherein the second gate electrode is formed as a mesh having a plurality of elliptical shapes.

8. The power semiconductor device of claim 6, wherein the second gate electrode is formed as a mesh having a plurality of octagonal shapes.

9. The power semiconductor device of claim 6, further comprising:
a variable conductivity layer formed in the third semiconductor layer between the junction layer and the second gate electrode.

10. A power semiconductor device, comprising:
a drain electrode and a source electrode having a semiconductor portion disposed therebetween, wherein the semiconductor portion comprises:
a drain layer having a first conductivity type;
a drift layer having the first conductivity type disposed on the drain layer, the drain layer having an effective impurity concentration that is greater than an effective impurity concentration of the drift layer;
abase layer having a second conductivity type that is different than the first conductivity type;
a semiconductor layer comprising a plurality of source layers having the first conductivity type and a plurality of contact layers having the second conductivity type; and
a first gate electrode formed between adjacent source layers of the semiconductor layer, the first gate electrode extending to the drift layer through the base layer, wherein at least two regions are formed in the semiconductor portion with different effective impurity concentration of the base layer and the source layers.

11. The power semiconductor device of claim 10, wherein the at least two regions have different threshold voltages.

12. The power semiconductor device of claim 10, wherein the at least two regions have different channel lengths.

13. The power semiconductor device of claim 10, wherein the first gate electrode and the drain layer, the drift layer, the base layer, the source layers and the contact layers comprise parts of a first transistor.

14. The power semiconductor device of claim 13, further comprising:
a junction layer disposed through the base layer to separate portions of the source layers, the junction layer comprising a protruded portion of the second semiconductor layer.

15. The power semiconductor device of claim 14, wherein a second gate electrode is formed in the junction layer, the second gate electrode comprising a part of a second transistor.

16. The power semiconductor device of claim 14, wherein the second gate electrode is formed as a mesh having a plurality of elliptical shapes.

17. The power semiconductor device of claim 14, wherein the second gate electrode is formed as a mesh having a plurality of octagonal shapes.

18. The power semiconductor device of claim 14, further comprising:
a variable conductivity layer disposed in the third semiconductor layer between the junction layer and the second gate electrode.

19. A method for manufacturing a power semiconductor device, the method comprising:
forming a first layer having a first conductivity type;
forming a second layer on the first layer, the second layer having the first conductivity type, wherein the first layer has an effective impurity concentration that is greater than an effective impurity concentration of the second layer;
forming a third layer on the second layer, the third layer having a second conductivity type that is different than the first conductivity type;
forming a fourth layer comprising a plurality of semiconductor layers having the first conductivity type and the second conductivity type; and
forming a first transistor between adjacent semiconductor layers of the fourth layer, the adjacent layers having the first conductivity type, and the first gate electrode extending to the second layer through the third layer, wherein at least two regions are formed in the power semiconductor device, and each of the regions has a different threshold voltage.

20. The method of claim 19, further comprising:
forming a junction layer on the third layer, the junction layer comprising a protruded portion of the second semiconductor layer to form a second transistor.
